(19) United States
(12) Patent Application Publication
(10) Pub. No.: US 2021/0074518 A1
(43) Pub. Date: Mar. 11, 2021

(54) PLASMA PROCESSING APPARATUS AND TEMPERATURE CONTROL METHOD

(71) Applicant: Tokyo Electron Limited, TOKYO (JP)

(72) Inventors: Satoru KAWAKAMI, Yamanashi (JP); Taro IKEDA, Yamanashi (JP)

(21) Appl. No.: 17/009,904

(22) Filed: Sep. 2, 2020

(30) Foreign Application Priority Data
Sep. 9, 2019 (JP) 2019-163795

(51) Int. Cl. H01J 37/32; C23C 16/52; C23C 16/511; C23C 16/44; C23C 16/34

(52) U.S. Cl. CPC H01J 37/32522; H01J 37/32192; H01J 37/32724; H01J 37/3244; H01J 37/32862; H01J 2237/334; C23C 16/511; C23C 16/4405; C23C 16/345; H01J 2237/2001; C23C 16/52

(57) ABSTRACT

A plasma processing apparatus includes a processing container in which a plasma processing is performed on a substrate; a plurality of microwave radiation mechanisms, a stage arranged in the processing container to accommodate the substrate thereon and including a lower heating source; and an upper heating source provided on the upper portion of the processing container and arranged at a position that faces the stage.

### CROSS-REFERENCE TO RELATED APPLICATION

This application is based on and claims priority from Japanese Patent Application No. 2019-163795 filed on Sep. 9, 2019 with the Japan Patent Office, the disclosure of which is incorporated herein in its entirety by reference.

### TECHNICAL FIELD

The present disclosure relates to a plasma processing method and a temperature control method.

### BACKGROUND

In a plasma processing apparatus described in Japanese Patent Laid-Open Publication No. H11-016858, after a Ti film is formed at 650° C., the temperature is lowered to 200 to 300° C., and then, NF₃ gas is introduced into a processing container for cleaning. After the cleaning process is completed, the temperature is raised again to 650° C. and the Ti film formation is started.

### SUMMARY

In an embodiment, a plasma processing apparatus includes a plurality of microwave radiation mechanisms, a stage, a lower heating source, and an upper heating source. The plurality of microwave radiation mechanisms are provided on an upper portion of a processing container. The stage is arranged in the processing container. The lower heating source is provided in the stage. The upper heating source is arranged at a position facing the stage.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is an explanatory diagram illustrating a configuration of a plasma processing apparatus according to an embodiment.

FIG. 2 is a perspective view of an upper structure of the plasma processing apparatus.

FIG. 3 is a plan view of the upper structure of the plasma processing apparatus.

FIG. 4 is a bottom view of the upper structure of the plasma processing apparatus.

FIG. 5 is a vertical cross-sectional view of a microwave radiation mechanism.

FIG. 6 is a plan view of an upper heating source.

FIG. 7 is a plan view of another upper heating source.

FIG. 8 is a plan view of another upper structure of the plasma processing apparatus.

FIG. 9 is a plan view of still another upper structure of the plasma processing apparatus.

FIG. 10 is a system configuration diagram of the plasma processing apparatus.

FIG. 11 is a timing chart illustrating changes in temperature with time.

FIG. 12 is an explanatory diagram illustrating the configuration of the plasma processing apparatus according to the embodiment.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

Various embodiments will be described below.

In an embodiment, a plasma processing apparatus includes a plurality of microwave radiation mechanisms provided in an upper portion of a processing container, a stage arranged in the processing container, a lower heating source provided in the stage, and an upper heating source arranged at a position facing the stage.

When a processing gas is introduced in the initial stage of film formation, a substrate temperature is lowered and the quality of the film formed by the plasma processing may not be improved. In the embodiment, since heating may be performed from both the lower heating source and the upper heating source in the initial stage of film formation by the plurality of microwave radiation mechanisms, it is possible to suppress a decrease in substrate temperature. As a result, it is possible to suppress the temperature decrease due to the gas introduction and the film density decrease due to the temperature decrease. Therefore, a high quality film may be formed. In particular, by providing a plurality of microwave radiation mechanisms, it is possible to maintain and improve the in-plane uniformity of plasma, secure a space for disposing the upper heating source, and perform appropriate heating.

In the plasma processing apparatus according to the embodiment, the upper heating source is a heating lamp. The heating lamp may rapidly heat an object from a position separated from the object and is suitable for suppressing a rapid temperature change.

The plasma processing apparatus according to the embodiment further includes a gas inlet provided in the processing container and connected to a gas source for film formation. The plasma processing apparatus may be used for purposes other than film formation but is particularly useful when used during film formation as described above. A gas for film formation may be introduced from the gas inlet, and the present apparatus may suppress the temperature decrease at the time of introducing the gas as described above.

The plasma processing apparatus according to the embodiment further includes a controller connected to the lower heating source and the upper heating source. According to an instruction from the controller, both the lower heating source and the upper heating source heat during the plasma processing. At the time of the cleaning, the lower heating source performs heating with an output of A % of the plasma processing, and the upper heating source performs heating with an output of B % (B<A) of the plasma processing.

That is, at the time of the cleaning, the heating output of the upper heating source is made lower than that at the time of the plasma processing (B<A). As a result, the temperature in the processing container (particularly, the temperature of the stage) may be lowered to a cleaning temperature in a short time, and the decrease in throughput due to the cleaning may be suppressed. Suitably, A % is 50% or more and 100% or less, and B % is 0% or more and 50% or less. In an example, the upper heating source may be stopped at the time of the cleaning (B %=0%), and the lower heating source may have a constant output (A %=100%) by taking the same output during the cleaning as that during the plasma processing. In this case, since the output of the lower heating source is constant, the temperature change in the processing container may be stabilized.

A temperature control method according to the embodiment is directed to the temperature control method in the plasma processing apparatus described above. The temperature control method includes radiating microwaves from a plurality of microwave radiation mechanisms to generate plasma during the plasma processing, and both the lower heating source and the upper heating source performing heating. Since both the lower heating source and the upper heating source heat during the plasma processing, it is possible to appropriately compensate for a rapid temperature decrease.

In a temperature control method according to the embodiment, during the cleaning, the lower heating source performs heating with an output of A % of the plasma processing, and the upper heating source performs heating with an output of B % (B<A) of the plasma processing. As described above, at the time of the cleaning, the heating output of the upper heating source is made lower than that at the time of the plasma processing (B<A). As a result, the decrease in throughput due to the cleaning is suppressed.

In the temperature control method according to the embodiment, the lower heating source is controlled such that in the lower heating source alone, the temperature of the stage is lower than a temperature during the plasma processing during both the plasma processing and the cleaning. Further, at the time of the cleaning, the output of the upper heating source is reduced as compared to that at the time of the plasma processing, and the stage is controlled to the temperature at the time of the cleaning.

Hereinafter, the plasma processing apparatus according to the embodiment will be described. The same elements are denoted by the same reference symbols, and redundant descriptions thereof are omitted.

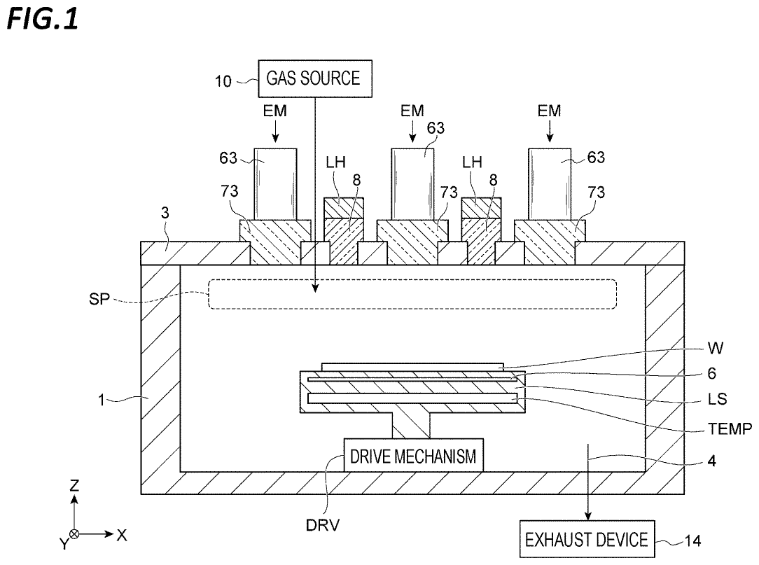

FIG. 1 is an explanatory diagram illustrating a configuration of the plasma processing apparatus according to the embodiment. For convenience of explanation, a three-dimensional orthogonal coordinate system is set. The vertical direction of the plasma processing apparatus is defined as the Z axis direction, and the two directions perpendicular thereto are defined as the X axis and the Y axis, respectively.

The plasma processing apparatus includes a processing container 1. The plasma processing apparatus includes a stage LS arranged in a lower portion of the processing container 1, and a substrate W to be processed is arranged on the stage LS. A lower heating source TEMP is provided in the stage LS. The plasma processing apparatus includes a plurality of microwave radiation mechanisms 63 provided on the upper portion of the processing container 1. The plasma processing apparatus includes an upper heating source LH arranged at a position facing the stage LS.

The stage LS includes a lower electrode 6 embedded in the main body of the stage, and a lower heating source TEMP serving as a temperature adjusting device embedded in the main body. The stage LS is supported by a drive mechanism DRV and may be moved in the Z axis direction by the drive mechanism DRV. The drive mechanism DRV is a Zθ stage, and may move in the Z axis direction and rotate in the XY plane.

The lower heating source TEMP preferably includes a resistance heating source, and heats the stage LS and/or the substrate W by supplying a current to a resistor having a high resistance value.

The lower electrode 6 forms a reference potential and may be fixed to the ground potential, but may be set to an impedance that attracts the plasma-generated ions, if necessary. Further, the lower electrode 6 may be applied with a DC potential or a potential obtained by superimposing an AC potential on a DC potential. Also, an electrostatic chuck may be provided on the stage LS.

The microwave radiation mechanism 63 is attached to a lid member 3 provided on the upper portion of the processing container 1 via a dielectric window 73. A plurality of dielectric windows 73 is provided in multiple openings in the lid member 3. The inside of the microwave radiation mechanism 63 constitutes a waveguide through which microwaves propagate. A waveguide or a coaxial tube may be used as the microwave waveguide. Further, the microwave radiation mechanism 63 propagates the microwaves generated by the microwave generator through the microwave waveguide and radiates the microwaves into the processing container 1. The space immediately below the dielectric window 73 for the plurality of microwave radiation mechanisms 63 is a plasma generation space SP, and plasma is generated in the plasma generation space SP according to the microwave (radio-frequency) EM introduced into the microwave radiation mechanism 63. Further, a processing gas is supplied from a gas source 10 to the inside of the processing container 1. Examples of the processing gas include a raw material gas for plasma film formation, and an etching gas for plasma etching. The gas in the processing container 1 is exhausted to the outside by the exhaust device 14 via an exhaust passage 4.

The upper heating source LH is attached to the lid member 3 via a transparent window 8. The plurality of transparent windows 8 are provided in the multiple openings in the lid member 3. The upper heating source LH is preferably a heating lamp, and in this example, an LED lamp is used. It is also possible to use a halogen lamp as a radiant heating source. Such a heating lamp is a rapid heating source having a higher rate of temperature rise than resistance heating, and may perform rapid temperature changes, but may also be used to suppress rapid temperature changes. As a wavelength of the LED lamp, for example, a wavelength of 855 nm may be used.

Light/electromagnetic waves such as infrared rays radiated from the upper heating source LH reach the stage LS or the substrate W on the stage LS beyond the plasma generation space SP. Therefore, the stage LS and/or the substrate W is heated by light/electromagnetic waves such as infrared rays radiated from the upper heating source LH. The transparent window 8 is made of a material which is transparent to light/electromagnetic waves such as infrared rays. The material of the dielectric window 73 is, for example, alumina (Al₂O₃), and the material of the transparent window 8 is, for example, quartz glass or anhydrous synthetic quartz.

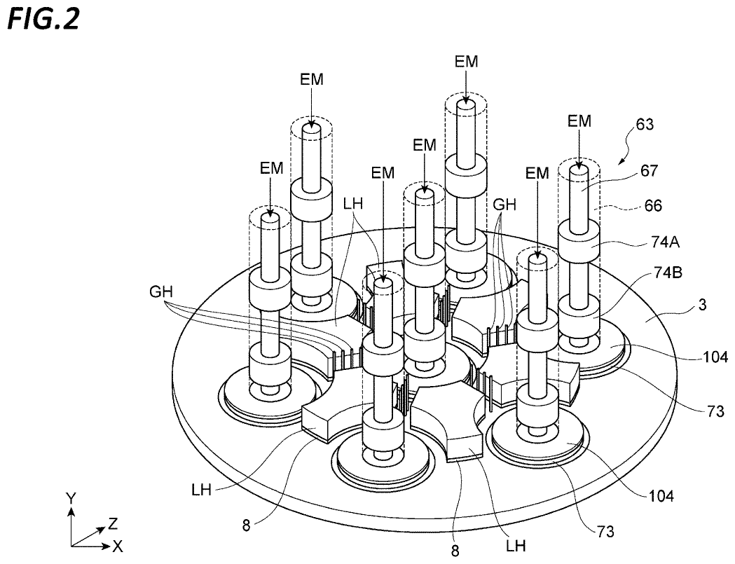

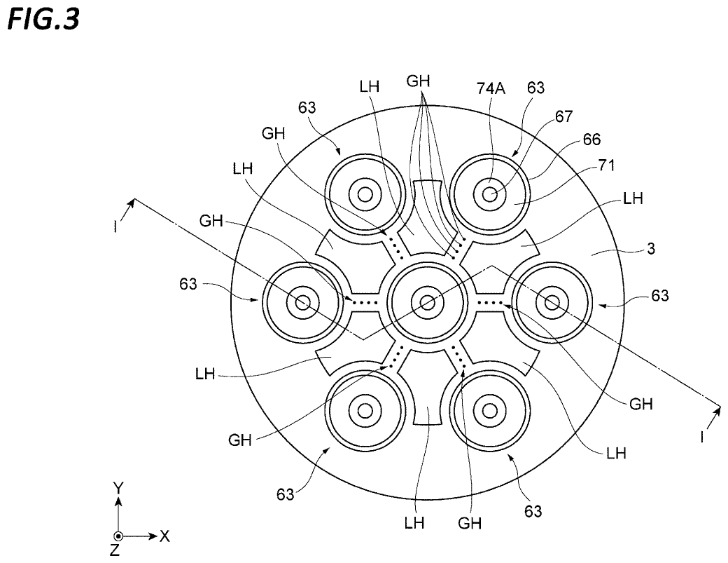

FIG. 2 is a perspective view of an upper structure of the plasma processing apparatus, and FIG. 3 is a plan view of the upper structure of the plasma processing apparatus. Further, the cross section taken along line I-I in FIG. 3 indicates the cross section in FIG. 1.

The lid member 3 is provided with a plurality of microwave radiation mechanisms 63 and a plurality of upper heating sources LH. The plurality of upper heating sources LH may be combined into one heating source. Seven microwave radiation mechanisms 63 are arranged on seven dielectric windows 73 provided on the lid member 3, respectively. The microwave radiation mechanism 63 includes an outer conductor 66 and an inner conductor 67 that form a coaxial tube for transmitting microwaves. The outer conductor 66 and the inner conductor 67 each extend along the Z axis direction. A first slug 74A and a second slug 74B are arranged between the outer conductor 66 and the inner conductor 67. The first slug 74A and the second slug 74B are each made of a dielectric material. Alumina (Al₂O₃) may be used as the dielectric material. The first slug 74A and the second slug 74B may function as slug tuners that perform an impedance adjustment by adjusting the positions of the slugs.

Referring back to FIG. 3, a planar shape of the lid member 3 is circular. Assuming a regular polygon (a regular hexagon in this example) taking the center of gravity of the lid member 3 as the center, six microwave radiation mechanisms 63 are arranged at the apex position of the regular polygon. The remaining one microwave radiation mechanism 63 is arranged at the center of gravity of the regular polygon. The upper heating source LH is arranged in a region between the microwave radiation mechanisms 63 adjacent to each other along the circumferential direction. The center of gravity of the upper heating source LH is closer to the center of gravity of the regular polygon than the center of gravity of the microwave radiation mechanism 63. A plurality of gas holes GH is arranged in the region between the upper heating sources LH adjacent in the circumferential direction. In each of the regions, the plurality of gas holes GH of this example are aligned on the radial line from the center of gravity of the regular polygon along the radial direction. The dielectric window 73 illustrated in FIG. 1 is located immediately below each microwave radiation mechanism 63.

As described above, the plasma processing apparatus includes the plurality of microwave radiation mechanisms 63, the stage LS, the lower heating source TEMP, and the upper heating source LH. The microwave radiation mechanisms are provided on the upper portion of the processing container 1. The stage LS is arranged in the processing container 1. The lower heating source TEMP is provided in the stage LS. The upper heating source LH is arranged at a position facing the stage LS.

The processing gas is introduced into the processing container 1 from the gas source 10 through the gas hole GH. In this case, in the initial stage of film formation, the substrate temperature is lowered by the processing gas, and the quality of the film formed by the plasma processing may not be improved. It is also possible to perform heating from both the lower heating source TEMP and the upper heating source LH at the initial stage of film formation by the plurality of microwave radiation mechanisms 63. This may prevent the substrate temperature from decreasing. It is possible to suppress the temperature decrease due to the gas introduction and the film density decrease due to the temperature decrease. Therefore, a high quality film may be formed. In particular, by providing a plurality of microwave radiation mechanisms 63, it is possible to maintain and/or improve the in-plane uniformity of plasma, secure a space for disposing the upper heating source LH, and perform appropriate heating.

The plasma processing apparatus is provided in the processing container 1 and includes a gas inlet (gas hole GH: see FIG. 2) connected to a gas source for film formation. The plasma processing apparatus may be used for purposes other than film formation but is particularly useful when used during film formation. A gas for film formation may be introduced from the gas inlet, and the present apparatus may suppress the temperature decrease at the time of introducing the gas as described above.

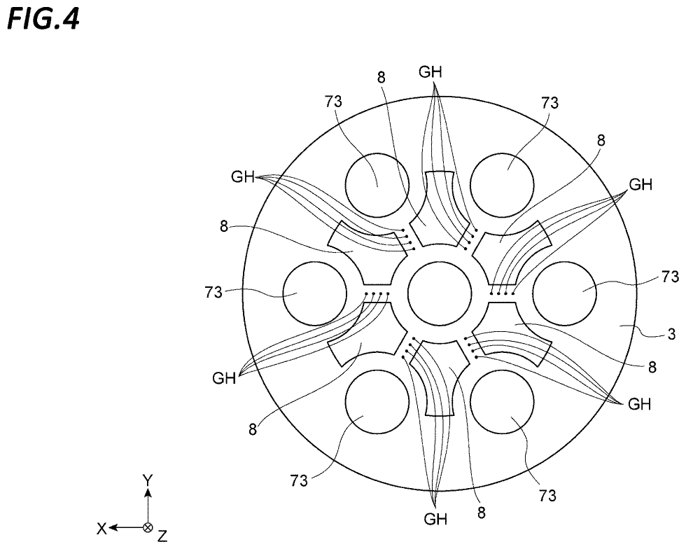

FIG. 4 is a bottom view of the upper structure of the plasma processing apparatus.

On the back surface side of the lid member 3 (inside the processing container), the back surfaces of the dielectric windows 73 and the back surfaces of the transparent windows 8 are exposed. A positional relationship of the dielectric window 73 with respect to the lid member 3 is the same as a positional relationship of the microwave radiation mechanism 63 with respect to the lid member 3. Similarly, a positional relationship of the transparent window 8 with respect to the lid member 3 is the same as a positional relationship of the upper heating source LH with respect to the lid member 3. A plurality of gas holes GH is arranged in a region between the transparent windows 8 adjacent in the circumferential direction. In each of the regions, the plurality of gas holes GH of this example are aligned on the radial line from the center of gravity of the regular polygon along the radial direction. Further, the regular polygon is not limited to a hexagon, but may be a polygon such as a triangle, a quadrangle, a pentagon, or a heptagon.

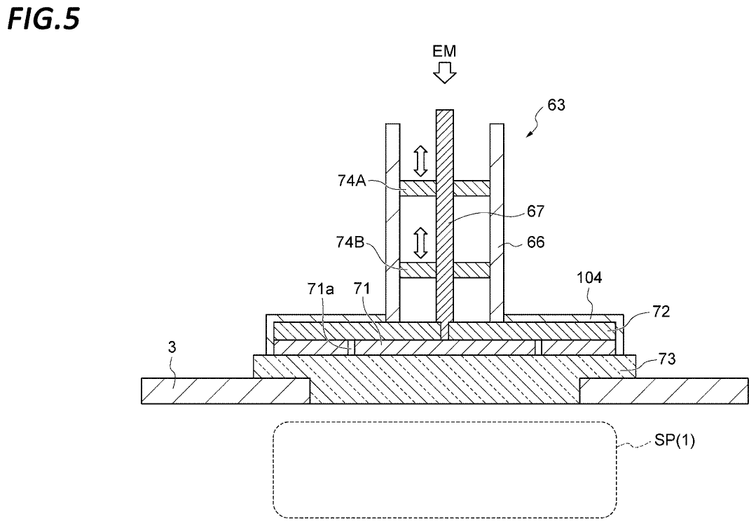

FIG. 5 is a vertical cross-sectional view of a microwave radiation mechanism.

The dielectric window 73 is fitted in the opening of the lid member 3. The dielectric window 73 has flat upper and lower surfaces. The upper surface has a larger radius than the lower surface and is engaged with the opening end surface of the lid member 3. In the figure, the upper side surface of the dielectric window 73 is not in contact with the lid member 3. Further, the upper portion of the lid member 3 may be processed into a step shape so that the upper side surface of the dielectric window 73 is embedded in the lid member 3. Immediately below the dielectric window 73, plasma of the introduced processing gas is generated and a plasma generation space SP is formed. When a first plasma generation space SP is referred to as SP(1), the N plasma generation spaces may be expressed as plasma generation spaces SP(1) to SP(N). In this example, seven plasma generation spaces (N=7) exist corresponding to the positions of the microwave radiation mechanisms 63. The plasma generation spaces SP(1) to SP(7) are arranged at six apex positions and one centroid position of a virtual regular polygon (regular hexagon in this example).

A planar antenna 71 is arranged on the dielectric window 73. The planar antenna 71 is a slot plate having a plurality of slots 71a, and microwave energy is radiated from these slots 71a through the dielectric window 73 toward the inside of the processing container 1. The shape of the slot 71a is an arc shape that extends to surround the center of the planar antenna 71, but is not limited thereto. For example, a plurality of L-shaped slots or slots of two line segments that are closely spaced and form an obtuse angle (C-shaped) may be arranged concentrically.

A microwave slow wave material 72 including a dielectric material is arranged on the planar antenna 71. The microwave slow wave material 72 is located between the planar antenna 71 and an upper metal plate 104. The upper metal plate 104 covers the microwave slow wave material 72 and is continuous with the outer conductor 66 of a coaxial tube. The microwave slow wave material 72 is made of a dielectric material such as quartz, ceramics, a fluorine resin such as polytetrafluoroethylene, or a polyimide resin. The materials of the planar antenna 71 and the coaxial tube are not particularly limited when they are conductors, and for example, copper or stainless steel may be used.

The inner conductor 67 of the coaxial tube passes through the centers of the first slug 74A and the second slug 74B made of a dielectric material, and the first and second slugs may move in the axial direction. The slugs are moved up and down by a moving device (not illustrated). A lower end of the inner conductor 67 passes through the microwave slow wave material 72 and reaches the planar antenna 71. When the microwave propagating from above in the coaxial tube reaches the plane antenna 71, the microwave slow wave material 72 is radially diffused along the extending horizontal direction and is radiated downward from the slot 71a of the planar antenna 71.

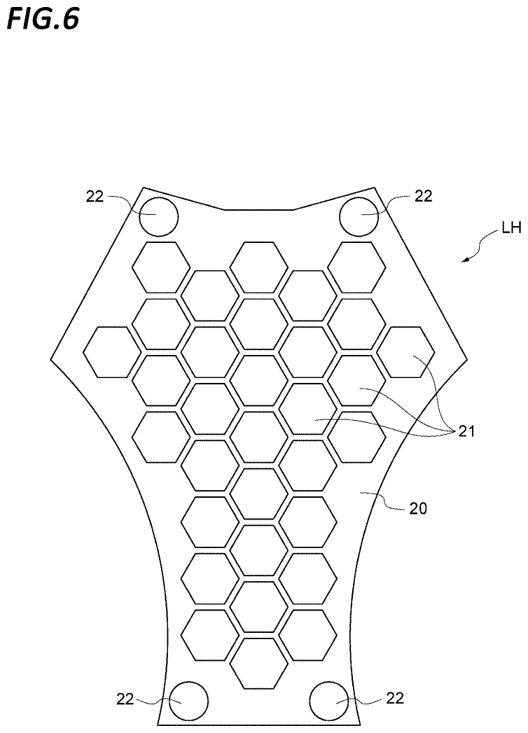

FIG. 6 is a plan view of an upper heating source.

The upper heating source LH in this example is an LED lamp. The LED lamp includes a support substrate 20, a plurality of light emitting semiconductor chips 21 fixed on the support substrate 20, and spacers 22 fixed on the support substrate 20. A light emitting surface of the light emitting semiconductor chip 21 faces downward and faces the internal space of the processing container 1. The shape of one light emitting semiconductor chip 21 is a hexagon, and the plurality of light emitting semiconductor chips 21 are arranged in a honeycomb shape. The upper heating source LH is fixed to the transparent window 8 immediately below (see FIG. 1). A lower end of the spacer 22 contacts the transparent window 8 or the lid member 3 to separate the light emitting semiconductor chip 21 from the transparent window 8. In this example, four spacers 22 are illustrated at the corners of the support substrate 20, but the number thereof is not limited thereto. Each of the light emitting semiconductor chips 21 includes a plurality (e.g., six) of semiconductor light emitting diodes (LEDs). By laying out the light emitting semiconductor chips 21 including a plurality of LEDs, the amount of light per unit area is increased.

Each LED includes an anode and a cathode, which are connected to a wiring (not illustrated) provided on the support substrate 20. A drive circuit (not illustrated) may be arranged on the back surface side (the upper surface side) of the support substrate 20, and the drive circuit is connected to each LED.

The shape of the support substrate 20 will be described. A circumferential direction of the lid member 3 is defined as a width direction of the support substrate 20. A region located closer to the center of the lid member 3 than the position where a dimension of the support substrate 20 in the width direction is the largest is defined as a first region (upper region), and a region located closer to the peripheral portion of the lid member 3 than the position where the dimension of the support substrate 20 in the width direction is the largest is defined as a second region (lower region). The planar shape of the upper region of the support substrate 20 is such that the width becomes smaller toward the center of the lid member 3, and the side facing the center of the lid member 3 is recessed toward the peripheral portion. The recessed side faces the microwave radiation mechanism 63 located at the center of the lid member 3. The planar shape of the lower region of the support substrate 20 has a shape in which the width increases toward the center of the lid member 3, and the two sides defining the width form an arc. These arcs face the microwave radiation mechanism 63 adjacent to the lid member 3 in the circumferential direction. By using the support substrate 20 having such a shape, many light emitting semiconductor chips 21 may be laid out.

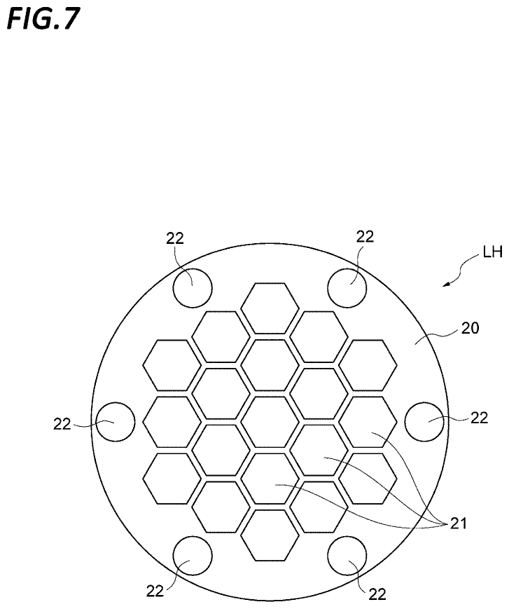

FIG. 7 is a plan view of another upper heating source.

Although the upper heating source LH of this example is an LED lamp, the upper heating source LH is different from that illustrated in FIG. 6 only in the shape of the support substrate 20, the arrangement of the light emitting semiconductor chips 21, and the arrangement of the spacers 22, and the other points are the same. The support substrate 20 has a circular shape, and the light emitting semiconductor chips 21 are laid out in concentric circles to surround the semiconductor light emitting chip at the center. A plurality of spacers 22 is arranged along the outer peripheral portion of the support substrate 20. In addition to the above-described structure, the support substrate 20 having such a shape may be applied to the upper heating source LH having the following arrangement.

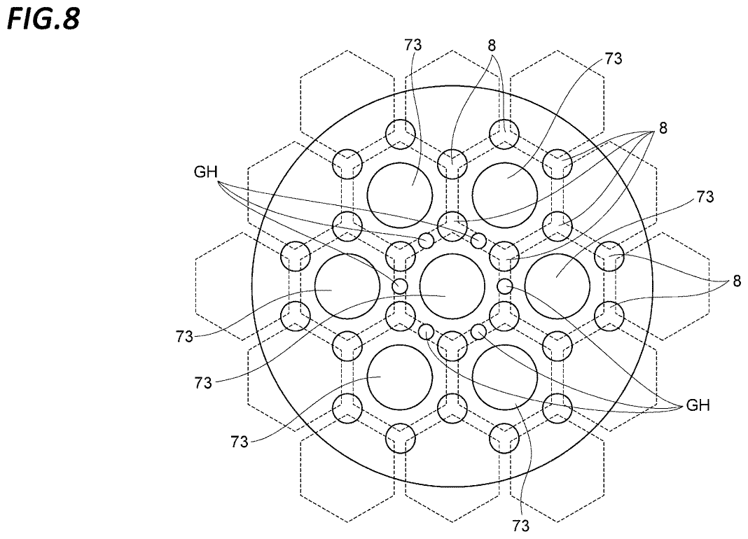

FIG. 8 is a plan view of another upper structure of the plasma processing apparatus, and illustrates the shape in the XY plane as in FIG. 3

The microwave radiation mechanism 63 described above is arranged at the position where the dielectric window 73 is arranged, and the upper heating source LH described above is arranged at the position where the transparent window 8 is arranged. Here, only the window material is illustrated for the sake of clarifying the position, and the microwave radiation mechanism 63 and the upper heating source LH are not illustrated.

A regular hexagon including the center of the circular lid member 3 is virtually set, the dielectric window 73 is arranged at the center position, and the transparent window 8 is arranged at the apex position of the regular hexagon. Six regular hexagons are virtually set to surround the central regular hexagon, the dielectric window 73 is arranged at the center of each regular hexagon, and the transparent window 8 is arranged at the apex position of each regular hexagon. Therefore, in the two-dimensional plane, the transparent window 8 and the upper heating source LH are evenly distributed, and the uniformity of plasma is improved. Gas holes GH are provided in the region between the adjacent transparent windows 8, and the processing gas may be supplied from the gas holes GH.

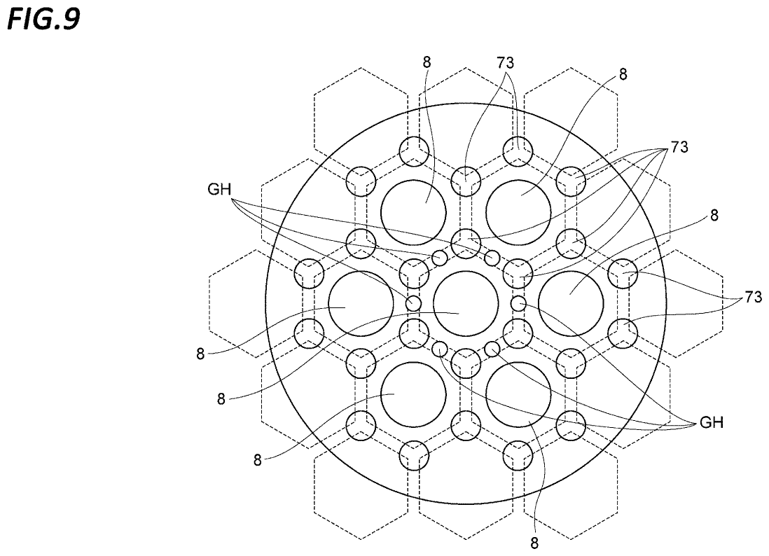

FIG. 9 is a plan view of still another upper structure of the plasma processing apparatus.

In the arrangement illustrated in the figure, the positions of the dielectric window 73 and the transparent window 8 illustrated in FIG. 8 are replaced with each other. The microwave radiation mechanism 63 described above is arranged at the position where the dielectric window 73 is arranged, and the upper heating source LH described above is arranged at the position where the transparent window 8 is arranged. According to such a configuration, since the number of microwave radiation mechanisms 63 per unit area is larger than that illustrated in FIG. 8, the uniformity of plasma in the two-dimensional plane becomes higher.

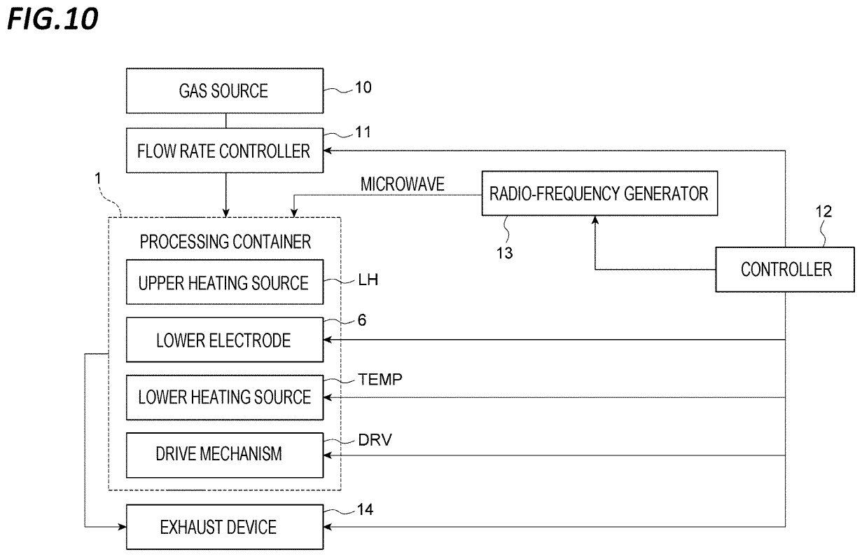

FIG. 10 is a system configuration diagram of the plasma processing apparatus.

The plasma processing apparatus described above includes a lower heating source TEMP, an upper heating source LH, and a radio-frequency generator 13 (microwave generator) that introduces microwaves for plasma generation into each microwave radiation mechanism 63. When microwaves are introduced into the processing container 1 from the radio-frequency generator 13 via the microwave radiation mechanism 63, plasma is generated inside the processing container 1. Since the processing gas may be supplied into the processing container 1 through the gas holes described above, plasma of the processing gas may be generated and a plasma processing may be performed on a processing target.

The plasma processing apparatus includes an upper heating source LH, a lower electrode 6, a lower heating source TEMP, a drive mechanism DRV, an exhaust device 14, a flow rate controller 11, and a controller 12 connected to the radio-frequency generator 13. These elements operate according to an instruction from the controller 12.

The substrate as the processing target is, for example, a wafer, and is placed on the stage LS (see FIG. 1). The stage LS may be moved in the vertical direction by the drive mechanism DRY. Thus, a distance between plasma and the substrate W (wafer) as the processing target placed on the stage LS may be set to the optimum condition. In other words, the plasma distribution state may be changed by moving the position of the stage LS. Therefore, by moving the stage so that the plasma is generated most uniformly and stably, the in-plane uniformity of the plasma may be enhanced.

The lower heating source TEMP includes a medium passage in which a cooling medium flows, a heating element (heater: resistance heater), and a temperature sensor. The stage LS (see FIG. 1) is controlled by the controller 12 to reach a target temperature. For example, in a case where the target temperature is T1° C., when the output of the temperature sensor is smaller than T1° C., the heater is heated, and when the output of the temperature sensor is higher than T1° C., the heater is not heated and the cooling medium may be controlled to flow in the medium passage. Here, the heating element as the lower heating source TEMP is preferably embedded in the stage LS (see FIG. 1), and may be made of a material such as refractory metal or carbon. Further, a wire for power supply is connected to the heating element.

The controller 12 also controls the exhaust device 14. The exhaust device 14 exhausts the gas in the processing container 1 to the outside via an exhaust passage 4 (see FIG. 1). Thus, the gas in the plasma generation space SP (see FIG. 1) may be exhausted, and the pressure in this space may be set to an appropriate value. This pressure may be changed according to the processing content, but may be set to, for example, 0.1 Pa to 100 Pa. As the exhaust device 14, a pump normally used in a vacuum system device such as a rotary pump, an ion pump, a cryostat, or a turbo molecular pump may be adopted.

The controller 12 controls the flow rate controller 11 that controls the flow rate of the gas supplied from the gas source 10. The flow rate controller 11 may be a simple valve. As a result, the target gas may be introduced into the processing container 1. Further, the controller 12 also controls the radio-frequency generator 13. The frequency of the radio-frequency is microwave in this example.

Examples of gases that may be used for the gas source 10 include rare gases such as Ar, gases containing carbon and fluorine such as CF₄ and C₄F₈, and gases such as SiH₄, N₂, and O₂. In addition to film deposition, plasma processing such as etching may be performed according to the type of the processing gas. When the plasma film forming process of the present apparatus is used, it is considered that in addition to silicon nitride (which is formed by applying plasma of SiH₄ and nitrogen or plasma of NH₃), the film quality of SiO₂ (which is formed by applying plasma of SiH₄ and oxygen) is remarkably improved.

Aluminum or copper may be used as the material of the lower electrode 6. Ceramics may be used as the material of the stage LS. The ceramic material is, for example, aluminum nitride (AlN). AlN has the advantages of high heat resistance and high resistance to plasma.

Silicon may be used as the substrate placed on the stage LS (see FIG. 1), and a processing such as film formation or etching may be performed on the substrate. Further, if necessary, an electrostatic chuck may be provided, the lower electrode 6 may be set to have an impedance for attracting ions, or a radio-frequency potential may be applied to the lower electrode 6 in certain cases. A configuration in which a magnet is arranged around the processing container 1 may also be considered.

Next, descriptions will be made on a control of the upper heating source LH and the lower heating source TEMP by the controller 12.

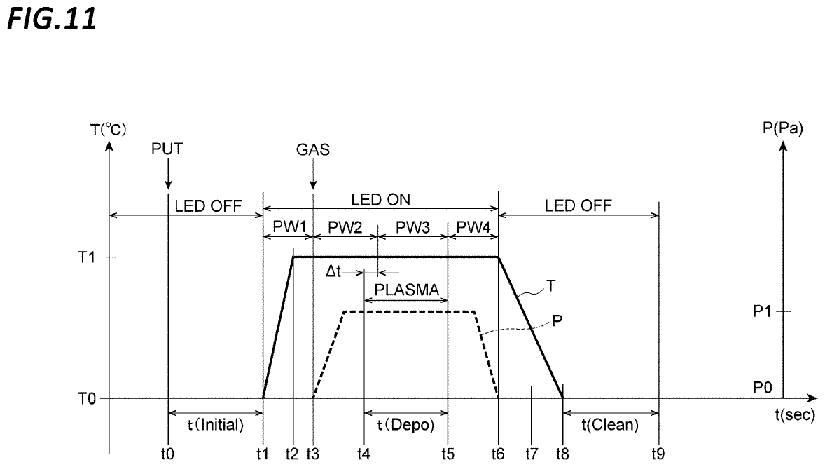

FIG. 11 is a timing chart illustrating changes in temperature with time. The symbol “T” indicates the stage temperature or the substrate temperature, and the symbol “P” indicates the pressure inside the processing container.

At time t0, the substrate as the processing target is introduced into the processing container. At this time, since there is no power supply to the upper heating source consisting of the LED lamp (LED is OFF) and the lower heating source is energized (ON), the stage temperature is T0 (° C.). After the substrate is introduced into the processing container, the substrate temperature rises to T0 (° C.). The period from times t0 to t1 is the initial period in which film formation is not performed (t(Initial)).

At time t1, power supply to the upper heating source is started (LED is ON), and power supply is continued until time t6 when the film formation process ends. Within the period from times t1 to t6, a series of processing relating to film formation is performed. When the processing gas is a mixed gas of SiH₄ and nitrogen, silicon nitride is formed on the substrate.

After time t6, the substrate is quickly unloaded out of the processing container. Time t7 for unloading the substrate is set between times t6 and t8. Time t8 is set to, for example, the time when the stage temperature satisfies the condition of T0 (° C.) after the temperature drops. As the substrate unloading time becomes earlier, the throughput may be improved. The cleaning process is performed from time t8 after the substrate is unloaded. The cleaning process is a process of cleaning the SiNx film (silicon nitride film) attached to the stage. In the cleaning process, ClF₃ gas or NF₃ gas is introduced as a cleaning gas from a gas source into the processing container. The temperature during the cleaning process is lower than the temperature T1 (° C.) during the film formation. When T1 (° C.) is, for example, 650° C. (exemplary range of 450 to 850° C.), T0 (° C.) is, for example, 200 to 300° C. (exemplary range of 450° C. or lower). When the stage temperature reaches T0 (° C.), the cleaning gas is introduced into the processing container to perform cleaning. Whether plasma is generated during the cleaning depends on the gas species. When ClF₃ gas is used, plasma is stopped, but when NF₃ gas is used, plasma is generated. This is because when the cleaning gas is introduced at a temperature that greatly exceeds T0 (° C.), the inner wall of the container and the internal structures themselves of the container such as a stage are also etched away. After the cleaning process is performed during the period from times t8 to t9 (cleaning period: t(Clean)), a new substrate is introduced (loaded) into the processing container (time t0). Thereafter, a series of processing relating to film formation is performed from times t1 to t6. In the series of processing, the temperature inside the processing container is raised again to the film formation temperature T1 (° C.), for example, 650° C., and the film is formed. The details will be described below.

First, at time t1, power supply to the upper heating source is started (LED is ON). When the stage temperature (substrate temperature) reaches the film formation temperature T1 (° C.) (time t2), immediately at time t3, introduction of the processing gas (mixed gas of SiH₄ and nitrogen) into the processing container is started. The power supplied to the upper heating source during the preheating period from times t1 to t3 is defines as PW1.

Next, after the gas introduction is started (time t3), when the pressure of the processing gas in the processing container rises from the initial value P0 (Pa) to the specified value (P1) and stabilizes, the microwave is immediately supplied to generate the plasma (time t4), and film formation is started. The power supplied to the upper heating source during the processing gas introduction period from time t3 to time t4+Δt, which is slightly after time t4, is defined as PW2. When a processing gas is introduced in the initial stage of film formation, a substrate temperature is lowered and the quality of the film formed by the plasma processing may not be improved. In the present embodiment, in the initial stage of film formation by the plurality of microwave radiation mechanisms, the lowering of the substrate temperature may be suppressed by performing heating from both the lower heating source and the upper heating source and adjusting the power PW2 supplied to the upper heating source, for example, in real time. As a result, it is possible to suppress the temperature decrease due to the gas introduction and the film density decrease due to the temperature decrease. Therefore, a high quality film may be formed. In particular, by providing a plurality of microwave radiation mechanisms, it is possible to maintain and improve the in-plane uniformity of plasma, secure a space for disposing the upper heating source, and perform appropriate heating.

After the start of film formation (time t4), a plasma processing for film formation is performed until time t5. In the plasma processing period from time t4 to time t5 (film deposition period: t(Depo)), the power supplied to the upper heating source during the period excluding the initial period (Δt) is defined as PW3. The period Δt is set to, for example, about 1 to 10 seconds.

After the plasma processing is completed (time t5), the supply of the processing gas into the processing container is stopped, and when the pressure in the processing container is reduced to the initial value P0 (Pa) (time t6), the supply of power to the upper heating source is stopped. The power supplied to the upper heating source during the processing gas discharge period from time t5 to time t6 is defined as PW4.

Here, when the substrate is not taken out of the processing container after the processing from times t0 to t6, the processing may be restarted from time t1 and the processing up to time t6 may be repeated.

As described above, the plasma processing apparatus further includes a controller connected to the lower heating source and the upper heating source. According to an instruction from the controller, both the lower heating source and the upper heating source heat during the plasma processing (t(Depo)). At the time of the cleaning (t(Clean)), the lower heating source heats with an output of A % (e.g., A=100) of the plasma processing, and the upper heating source heats with an output of B % (B<A) (e.g., B=0) of the plasma processing.

That is, at the time of the cleaning, the heating output of the upper heating source is made lower than that at the time of the plasma processing (B<A). As a result, the temperature in the processing container (particularly, the temperature of the stage) may be lowered to a cleaning temperature in a short time, and the decrease in throughput due to the cleaning may be suppressed. Suitably, A % is 50% or more and 100% or less, and B % is 0% or more and 50% or less. In an example, the upper heating source is stopped (e.g., PW3×B %=0) during the cleaning (t(Clean)). The lower heating source may make the output during the cleaning (t(Clean)) the same as that during the plasma processing (t(Depo)) and keep the output constant (e.g., A %=100%). Since the output of the lower heating source is constant from times t0 to t9, it is possible to shorten the time required to change the temperature associated with the cleaning.

The temperature control method is directed to the temperature control method in the plasma processing apparatus described above. The temperature control method includes a step (period t(Depo)) of radiating microwaves from a plurality of microwave radiation mechanisms to generate plasma and both the lower heating source and the upper heating source performing heating during the plasma processing. Since the lower heating source and the upper heating source both heat from time t3 when the processing gas is introduced to the time of the plasma processing, it is possible to appropriately compensate for a rapid temperature decrease.

In the above temperature control method, during the cleaning (t(Clean)), the lower heating source performs heating with an output of A % (e.g., A %=100%) of the plasma processing (t(Depo)). At this time, the upper heating source performs heating with an output of B % (B<A) (e.g., B %=0%) of the plasma processing (t(Depo), PW3). As described above, at the time of the cleaning, the heating output of the upper heating source is made lower than that at the time of the plasma processing (B<A). As a result, the temperature in the processing container (particularly, the temperature of the stage) may be lowered to a cleaning temperature in a short time, and the decrease in throughput due to the cleaning may be suppressed.

Further, in the above temperature control method, during both the plasma processing (t(Depo)) and the cleaning (t(Clean)), the lower heating source is controlled such that in the lower heating source alone, a stage temperature is lower than the plasma processing temperature (T0° C.<T1° C.). Further, during the cleaning, the output of the upper heating source is reduced as compared to during the plasma processing, and the stage is controlled to the temperature during the cleaning (T0° C.).

In addition, when the above conditions are satisfied, the upper heating source heats slightly during the initial period t(Initial) and the cleaning period t(Clean), and may not be turned off. Further, during the power supply period to the upper heating source (times t1 to t6), the supplied powers PW1 to PW4 may be changed. For example, PW1<PW2=PW3>PW4 may be set. It is also possible to employ a step of lifting the substrate from the stage by using a support member to shorten the temperature raising time of the substrate when raising the temperature of the substrate to the temperature T1 (° C.) during film formation. It is also possible to employ a step of performing an annealing process in the same processing container by lifting the substrate from the stage using the support member after the film formation process and bringing the substrate close to the upper heating source. It is also possible to employ a step of performing an annealing process after the film forming process by increasing the output of the upper heating source while keeping the substrate on the stage to make the substrate temperature higher than the temperature at the time of the substrate processing.

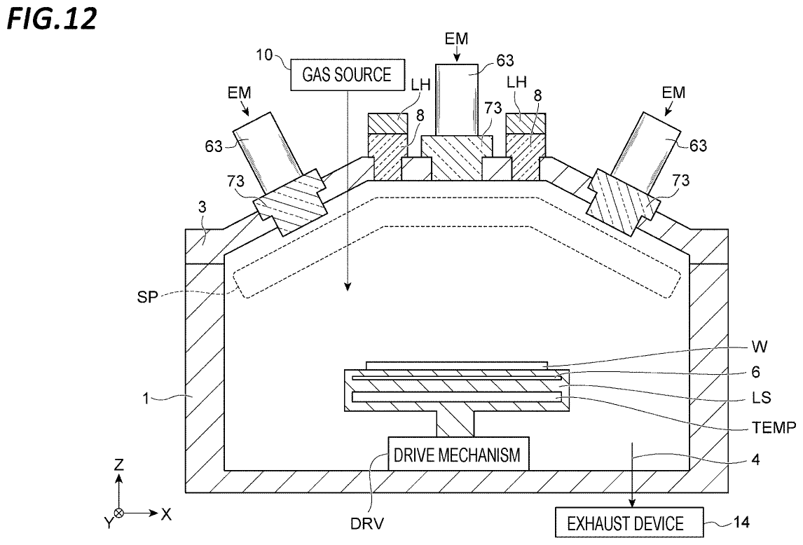

FIG. 12 is an explanatory diagram illustrating the configuration of the plasma processing apparatus.

The difference between the plasma processing apparatus illustrated in FIG. 12 and the plasma processing apparatus illustrated in FIG. 1 is that the peripheral portion of the lid member 3 extends obliquely from the horizontal plane. Therefore, the longitudinal directions of the coaxial tubes of the six microwave radiation mechanisms 63 in the peripheral portion illustrated in FIG. 1 are inclined from the vertical direction (Z axis direction), and other configurations are the same as those illustrated in FIG. 1.

The longitudinal direction of the coaxial tube of the microwave radiation mechanism 63 and the Z axis form an acute angle, and the microwave radiation mechanism 63 radiates microwaves obliquely toward the stage LS. A plasma generation space SP is formed according to the microwave radiation. In addition, in the above-described various structures, a structure in which the central microwave radiation mechanism 63 is omitted may be considered.

According to the plasma processing apparatus and the temperature control method thereof according to the embodiment, it is possible to form a good quality film.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a processing container configured to perform a plasma processing on a substrate;
a plurality of microwave radiators provided on an upper portion of the processing container;
a stage arranged in the processing container to accommodate the substrate thereon and including a lower heating source; and
an upper heating source provided on the upper portion of the processing container and arranged at a position facing the stage.

2. The plasma processing apparatus according to claim 1, wherein the upper heating source is a heating lamp.

3. The plasma processing apparatus according to claim 2, further comprising:
a gas inlet provided in the processing container and connected to a gas source for film formation.

4. The plasma processing apparatus according to claim 3, further comprising:
a controller configured to control an overall operation of the plasma processing apparatus including the lower heating source and the upper heating source such that
during a plasma processing, both the lower heating source and the upper heating source perform heating, and during a cleaning, the lower heating source heats with an output of A % of the plasma processing, and the upper heating source heats with an output of B % (B<A) of the plasma processing.

5. The plasma processing apparatus according to claim 4, wherein A % is 50% or more and 100% or less, and B % is 0% or more and 50% or less.

6. The plasma processing apparatus according to claim 1, further comprising:
a gas inlet provided in the processing container and connected to a gas source for film formation.

7. The plasma processing apparatus according to claim 1, further comprising:
a controller configured to control an overall operation of the plasma processing apparatus including the lower heating source and the upper heating source such that
during a plasma processing, both the lower heating source and the upper heating source perform heating, and during a cleaning, the lower heating source heats with an output of A % of the plasma processing, and the upper heating source heats with an output of B % (B<A) of the plasma processing.

8. The plasma processing apparatus according to claim 7, wherein A % is 50% or more and 100% or less, and B % is 0% or more and 50% or less.

9. A temperature control method comprising:
providing a plasma processing apparatus including a processing container that performs a plasma processing on a substrate, a plurality of microwave radiators provided on an upper portion of the processing container, a stage arranged in the processing container to accommodate the substrate thereon and including a lower heating source, and an upper heating source provided on the upper portion of the processing container and arranged at a position facing the stage;
during the plasma processing, radiating microwaves from the plurality of microwave radiators to generate plasma in the processing container, and causing both the lower heating source and the upper heating source to perform heating.

10. The temperature control method according to claim 9, further comprising:
during the cleaning, causing the lower heating source to perform heating with an output of A % of the plasma processing, and the upper heating source to perform heating with an output of B % (B<A) of the plasma processing.

11. The temperature control method according to claim 10, wherein during both the plasma processing and the cleaning, the lower heating source is controlled such that a temperature of the stage is lower than a temperature during the plasma processing, and
during the cleaning, an output of the upper heating source is lowered as compared with the plasma processing such that the temperature of the stage is controlled to be a temperature at the cleaning.
